(19) United States
(12) Patent Application Publication
(10) Pub. No.: US 2024/0142513 A1
(43) Pub. Date: May 2, 2024

(54) LIQUID COOLED TEST SYSTEM FOR TESTING SEMICONDUCTOR INTEGRATED CIRCUIT CHIPS

(71) Applicants: Antares Advanced Test Technologies (Suzhou) Limited, Jiangsu (CN); Smiths Interconnect Americas, Inc., Kansas City, KS (US)

(72) Inventors: Jiachun Zhou, Fremont, CA (US); Dexian Liu, Jiangsu (CN); Quynh Ngoc Nguyen, Fremont, CA (US); Qihai Liang, Jiangsu (CN)

(21) Appl. No.: 18/405,335

(22) Filed: Jan. 5, 2024

Related U.S. Application Data
(63) Continuation of application No. 17/571,271, filed on Jan. 7, 2022, now abandoned.

(30) Foreign Application Priority Data
Sep. 27, 2021 (CN) 202111137602.8
Nov. 5, 2021 (CN) 202111306143.1

(51) Int. Cl. G01R 31/28

(52) U.S. Cl. CPC G01R 31/2863

(57) ABSTRACT

A test socket for an IC chip includes a retainer positioned adjacent a load board, the retainer defining a plurality of apertures corresponding to contact pads on the load board; a plurality of contacts disposed in the plurality of apertures, the plurality of contacts configured to electrically couple the IC chip to the contact pads; a housing defining a chamber in fluid communication with an inlet, a liquid outlet, and a vapor outlet. The housing includes a body structure defining a plurality of cavities corresponding to the plurality of apertures and configured to receive the plurality of contacts therein, and a guide structure configured to receive the IC chip and position the IC chip in the chamber when engaged with the plurality of contacts. The chamber receives a two phase fluid coolant via the inlet to at least partially submerges the plurality of contacts in the two phase fluid coolant.

### CROSS REFERENCE TO RELATED APPLICATIONS

This application is a continuation of U.S. patent application Ser. No. 17/571,271 filed on Jan. 7, 2022, which claims priority to Chinese Patent Application No. 202111137602.8 filed on Sep. 27, 2021, titled Liquid Cooled Test Socket for Testing Semiconductor Integrated Circuit Chips, and Chinese Patent Application No. 202111306143.1 filed on Nov. 5, 2021, titled Liquid Cooled Test System for Testing Semiconductor Integrated Circuit Chips, the entire contents of which are incorporated herein by reference.

### FIELD

The field of the disclosure relates generally to a test system for testing semiconductor integrated circuit chips and, more specifically, a system including a liquid cooled test socket in which test socket contacts are at least partially submerged in the liquid coolant.

### BACKGROUND

Semiconductor integrated circuit (IC) chips are produced in various packages, or chip configurations, and are produced in large quantities. Production of IC chips generally includes testing of each IC chip package, or simply “IC chip,” in a manner that simulates an end-user's application of that chip. One manner of testing IC chips is to connect each IC chip through a test socket to a printed circuit board (PCB), or load board, that exercises various functionalities of the IC chip. The IC chip is then removed from the test socket and proceeds in the production process based on the results of the test. The test socket assembly can then be re-used to test many IC chips.

IC chip testing is often highly automated using robotic systems, e.g., “auto handlers,” to move IC chips into and out of test sites. This includes setting each IC chip in a test socket attached to a load board for a duration of the test, and removing the IC chip when testing is complete. Some robotic systems can handle from tens, or hundreds, of IC chips up to tens of thousands of IC chips per hour. Accordingly, precision and durability of the test socket are imperative. Moreover, modern IC chips incorporate greater densities of semiconductor components that operate at higher frequencies, with greater current throughput, and with greater power consumption. Adequately testing such IC chips generally results in significant heating of the IC chip and test socket, which can degrade the test socket over time and impact integrity of the testing itself if left unmitigated, resulting in a reduced lifecycle for the test socket. Accordingly, it is desirable to cool both the IC chip under test and the test socket through which the IC chip is coupled to the load board.

### BRIEF DESCRIPTION

In one aspect, a test socket for an IC chip includes a retainer configured to be positioned adjacent a load board, the retainer defining a plurality of apertures corresponding to contact pads on the load board; a plurality of contacts disposed in the plurality of apertures, the plurality of contacts configured to electrically couple the IC chip to the contact pads; a housing at least partially defining a chamber in fluid communication with an inlet, a liquid outlet, and a vapor outlet. The housing includes a guide structure configured to receive the IC chip and position the IC chip in the chamber when engaged with the plurality of contacts. The chamber is configured to receive a two phase fluid coolant via the inlet to at least partially submerge the plurality of contacts in the two phase fluid coolant.

In another aspect, a test system for a plurality of IC chips includes a test site, a fluid coolant system, and a handler system. The test site includes a test socket coupled to a load board. The test socket includes a housing, a plurality of contacts, and a guide structure. The housing at least partially defines a chamber. The plurality of contacts is disposed within a retainer structure within the chamber and electrically coupled to the load board. The guide structure is configured to receive each of the plurality of IC chips and position each IC chip in the chamber when engaged with the plurality of contacts. The fluid coolant system includes a reservoir configured to hold a two phase fluid coolant, an inlet pathway coupled between the reservoir and the test socket, the inlet pathway configured to carry the two phase fluid coolant to the test socket to at least partially fill the chamber, a liquid outlet pathway coupled between the reservoir and the test socket, the liquid outlet pathway configured to carry heated liquid coolant away from the test socket, and a vapor outlet pathway coupled between the reservoir and the test socket, the vapor outlet pathway configured to carry coolant vapor away from the test socket. The handler system is configured to move the plurality of IC chips from a feed container to the test site, and from the test site to an output container. The handler system includes a pick arm configured to set each IC chip into the guide structure of the test socket to engage with the plurality of contacts at least partially submerged in the two phase fluid coolant.

In yet another aspect, a method of testing an IC chip includes coupling a test socket to a load board. The test socket defines a chamber within which a plurality of contacts is disposed. The plurality of contacts are configured to electrically couple the IC chip to the load board. The method includes supplying a two phase fluid coolant to the chamber to at least partially submerge the plurality of contacts. The method includes receiving the IC chip in a guide structure of the test socket to position the IC chip in the chamber when engaged with the plurality of contacts. The method includes conducting, employing the load board, an electrical test of the IC chip. The method includes removing heated liquid coolant via a liquid outlet defined in the test socket. The method includes removing coolant vapor via a vapor outlet defined in the test socket.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1A is block diagram of a test system for IC chips;

FIG. 1B is a cross sectional diagram of an example test system for IC chips;

FIGS. 2A and 2B are schematic diagrams of one embodiment of a test socket for at least partially submerging test socket contacts in a fluid coolant;

FIG. 3 is a cross sectional diagram of one embodiment of a test socket for at least partially submerging test socket contacts in a fluid coolant;

FIG. 4 is a cross sectional diagram of another embodiment of a test socket for at least partially submerging an IC chip in a fluid coolant;

FIG. 5 is a schematic diagram of an example fluid coolant system for use with the test socket shown in FIG. 3 or FIG. 4;

FIG. 6 is a cross sectional diagram of another embodiment of a test socket for at least partially submerging an IC chip in a fluid coolant;

FIG. 7 is a schematic diagram of another example fluid coolant system for use with the test socket shown in FIG. 6;

FIG. 8 is a flow diagram of one embodiment of a method of testing an IC chip; and

FIG. 9 is a flow diagram of one embodiment of a method of testing an IC chip.

Although specific features of various embodiments may be shown in some drawings and not in others, this is for convenience only. Any feature of any drawing may be referenced and/or claimed in combination with any feature of any other drawing.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

Known systems and methods for cooling IC chips are generally limited to carrying heat away from the IC chip itself. For example, common cooling schemes utilize heat sinks, fans, or heat pipes to absorb heat from the package of the IC chip and release it into the ambient or other mass, such as a coolant reservoir. Such schemes generally fail to cool contact interfaces of the IC chip, contact probes in the test socket, or the test socket itself.

The disclosed test socket at least partially submerges its contacts in a fluid coolant and, in some embodiments, a liquid coolant. The test socket defines a sealed chamber resting on a top surface of the load board, and in which the test socket contacts interface with both the load board and the IC chip when inserted, i.e., the device under test (DUT). The sealed chamber receives a fluid coolant through an inlet, and the fluid coolant fills the sealed chamber to a level at least partially submerging the test socket contacts, for example, spring probes or rotational contacts. In certain embodiments the test socket contacts are entirely submerged as well as the contact balls or contact pads of the IC chip. In certain embodiments the IC chip is at least partially submerged and optionally entirely submerged.

The fluid coolant is electrically insulative and has a low and stable dielectric constant. For example, the fluid coolant may include a perfluorinated compound (PFC) such as perfluorohexane, perfluroro, or perfluorotripentylamine. PFCs are sometimes referred to as Fluorinert™, which is one example manufactured by 3M. The low electrical conductivity of the coolant prevents making a short circuit among the test socket contacts. The low dielectric constant preserves signal integrity of signals conducted through the test socket pins between the IC chip and the load board. Given a fluid coolant having a dielectric constant greater than that of a vacuum or ambient air, properties of the test socket may be modified to compensate for the additional dielectric material, i.e., fluid coolant, surrounding the test socket contacts. For example, cavities defined in a test socket to receive coaxial contacts may be dimensioned based on the dielectric constant of the fluid coolant that will flow through the chamber and through the cavities between the IC chip and the load board.

The fluid coolant may be a liquid around room temperature, i.e., when introduced to the chamber, and, in certain embodiments, has a relatively low vaporization threshold. Generally, the liquid coolant has a greater capacity for absorbing heat than a gaseous coolant. The liquid coolant is heated by the test socket, test socket contacts, and the IC chip. In some embodiments, the liquid coolant is heated below a threshold for vaporization and flows from the chamber through a liquid outlet. Such embodiments utilize a coolant referred to as single phase coolant, i.e., one operating in only the liquid phase. For example, the fluid coolant may have a vaporization threshold at or above about 100 degrees C. In other embodiments the vaporization threshold may be higher or lower.

Alternatively, the test socket, test socket contacts, and the IC chip raise the temperature of the liquid coolant above a threshold for vaporization (e.g., above about 40 to 60 degrees C.). Such a fluid coolant is sometimes referred to as a two phase coolant, i.e., it assumes both the gas and liquid states, or phases, at various points in the cooling process. The coolant vapor rises within the chamber and flows from the chamber through a vapor outlet. Some two phase embodiments may include both a liquid outlet and a vapor outlet for heated coolant. Seals applied between the test socket and the load board prevent leakage of liquid or vapor coolant at the interface. Likewise, in embodiments having a test socket constructed of two or more body structures, e.g., a socket body and a retainer, seals are applied between the body components to prevent leakage of liquid or vapor coolant at those interfaces. The vaporized coolant generally has a greater capacity for releasing heat efficiently once removed from the chamber.

The fluid coolant is supplied from a reservoir using an inflow pump, gravity, or other suitable motive force. Unheated, or fresh, fluid coolant flows into the chamber until a desired fill level is reached. Fill level may be detected, for example, by one or more sensors positioned on the test socket. The sensors may include, for example, a pressure transducer or optical sensor. In certain embodiments, one or more additional sensors may be positioned in the chamber, for example, to measure coolant temperature within the chamber. Heated coolant flows from the chamber through the outlet and into the same reservoir for cooling and recirculation, or a second reservoir for cooling and recirculation, or for disposal. Heated coolant flowing from the chamber may include liquid coolant, coolant vapor, or both. For example, in one embodiment, heated coolant flows from the chamber in liquid phase only. In an alternative embodiment, heated coolant flows from the chamber in both a liquid phase and gas phase.

Heated coolant must be chilled to enable recirculation, which may be achieved, for example, by a refrigerant chilling system. Heated coolant may flow from the chamber under pressure from the inlet or, alternatively, may be moved by an outflow pump, gravity, or other suitable motive force. The pressure of the heated fluid coolant may be measured using one or more pressure sensors disposed in the return coolant flow path. In certain embodiments, heated coolant is filtered to remove particulates or other contaminates before it reaches a pump, chiller, or reservoir. The flow of fluid coolant through the chamber may be regulated according to a flow algorithm based on measured, temperatures, pressures, flow rates, or other operational parameter. The flow algorithm may include a constant flow setpoint determined by a lookup table or programmed by a user according to IC chip size and power demand. Alternatively, the flow algorithm may dynamically regulate outflow to achieve a desired coolant exit temperature setpoint or a desired coolant pressure setpoint, for example.

The fluid coolant system may be incorporated into a test system referred to as an auto handler system or provided independently. In certain embodiments, the fluid coolant system services multiple test sockets, or test sites, within an auto handler system, enabling greater efficiencies in scale of the fluid coolant system. The test system, or auto handler, may include additional ventilation equipment to evacuate coolant vapor that escapes the test socket. Likewise, in certain embodiments, additional sealants or seals may be incorporated into the test system enclosure to ensure coolant vapor does not escape the test system.

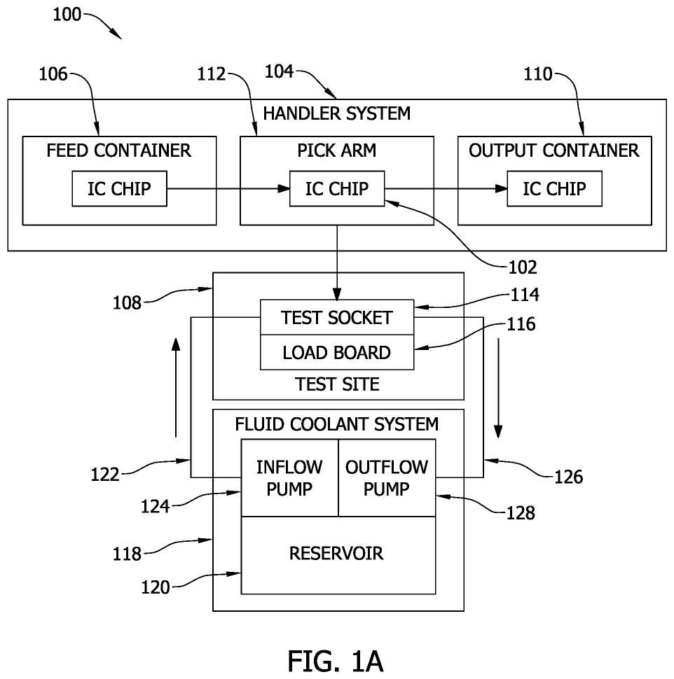

FIG. 1A is block diagram of a test system 100 for IC chips 102. FIG. 1B is a cross sectional schematic diagram of test system 100. Test system 100 is sometimes referred to more generally as an “auto handler” or “automated test equipment.” Test system 100 is an automated system for conducting electrical tests on thousands of IC chips 102 in a given period of time. Test system 100 includes a handler system 104 that moves IC chips from an input, or feed, container 106 to one or more test sites 108, and then to an output container 110. Feed container 106 may include, for example, a molded tray for precisely orienting and securing each IC chip 102 as it moves through handler system 104. Likewise, output container 110 may include, for example, one or more output trays or bins for collecting IC chips that “pass” or “fail” the electrical testing. In some embodiments, feed container 106 and output container 110 may be a single container as illustrated in FIG. 1B. Handler system 104 also includes a pick arm 112, or pick system, that acquires an IC chip 102 from feed container 106 and sets the IC chip 102 into a test socket 114 at a given test site 108. Pick arm 112 may, in certain embodiments, continue to apply force to the IC chip 102 under test in the direction of the test socket, e.g., downward, for the duration of the electrical test. Alternatively, pick arm 112 may release the IC chip 102 under test for the duration of the test. When the electrical testing is complete, pick arm 112 removes IC chip 102 from test socket 114 and disposes of the IC chip 102 in output container 110, which may include, for example, a pass bin and a fail bin. Pick arm 112 then acquires another IC chip 102 from feed container 106 for another cycle of electrical testing.

Test system 100 may include one or multiple test sites 108 and handler systems 104. Moreover, each handler system 104 may supply IC chips 102 to multiple test sites 108 and multiple test sockets 114. FIG. 1 illustrates a single handler system 104 for a single test site 108 and a single test socket 114 for clarity only.

Each test socket 114 is mounted, or coupled, to a surface of a load board 116. Load board 116 is a printed circuit board (PCB) configured to conduct automated electrical tests on a given IC chip, such as IC chip 102. Load board 116 can host one or more test sockets 114 for essentially simultaneous electrical testing of multiple IC chips 102. For example, a given test site 108 may include one or more load boards 116, each having one or more test sockets 114 mounted thereon.

Test system 100 includes a fluid coolant system 118. Fluid coolant system 118 includes a reservoir 120 of fluid coolant and, in some embodiments, a coolant that is liquid at temperatures around room temperature, e.g., around 20-25 degrees Celsius and, in certain embodiments, has a relatively low vaporization threshold, e.g., in a range of about 40 to 60 degrees Celsius. Such a coolant is referred to as a two-phase coolant. In alternative embodiments, the vaporization threshold may be higher, e.g., about 60 to 70 degrees Celsius, about 70 to 80 degrees Celsius, about 80 to 90 degrees Celsius, about 90 to 100 degrees Celsius, or any other suitable threshold temperature for the specific test socket and testing system. The fluid coolant is electrically insulative, or non-conductive, and has a low dielectric constant. The fluid coolant is supplied from reservoir 120 through an inflow pathway 122 to one or more test sites 108, each having one or more test sockets 114. Fluid coolant may be supplied with the assistance of an inflow pump 124, gravity, or any other suitable motive force. The liquid coolant is heated by test socket 114, test socket contacts, and IC chip 102. In some embodiments, the liquid coolant is heated below a threshold for vaporization and flows from the chamber through a liquid outlet. Such embodiments utilize a coolant referred to as single phase coolant, i.e., one operating in only the liquid phase. For example, the fluid coolant may have a vaporization threshold at or above about 100 degrees C.

Alternatively, test socket 114, test socket contacts, and IC chip 102 raise the temperature of the liquid coolant above a threshold for vaporization (e.g., above about 40 to 60 degrees C.). Such a fluid coolant is sometimes referred to as a two phase coolant, i.e., it assumes both the gas and liquid states, or phases, at various points in the cooling process. The coolant vapor rises within the chamber formed by test socket 114 and flows from the chamber through a vapor outlet. Some two phase embodiments may include both a liquid outlet and a vapor outlet for heated coolant.

Fluid coolant is removed, once heated at the test site 108, through an outflow pathway 126 and returned to reservoir 120 to be cooled and recirculated. Heated coolant flowing from the chamber may include liquid coolant, coolant vapor, or both. For example, in one embodiment, heated coolant flows from test site 108 in liquid phase only. In an alternative embodiment, heated coolant flows from test site 108 in both a liquid phase and gas phase.

Heated coolant must be chilled to enable recirculation, which may be achieved, for example, by a refrigerant chilling system. Heated coolant may flow from the chamber under pressure from the inlet or, alternatively, may be moved by an outflow pump, gravity, or other suitable motive force. The pressure of the heated fluid coolant may be measured using one or more pressure sensors disposed in the return coolant flow path. In certain embodiments, heated coolant is filtered to remove particulates or other contaminates before it reaches a pump, chiller, or reservoir.

In alternative embodiments, heated fluid coolant may be returned through outflow pathway 126 to a second reservoir (not shown) for cooling and, in certain embodiments, recirculation to reservoir 120. Inflow pathway 122 and outflow pathway 126 each include a suitable fluid tubing or pipe, including, for example, metal or plastic tubing. Fluid coolant may flow through outflow pathway 126 toward reservoir 120 with the assistance of an outflow pump 128, gravity, or any other suitable motive force.

In certain embodiments, fluid coolant system 118 includes a pump controller (not shown) having one or more processing devices and memory configured to operate, i.e., control torque or speed output of, inflow pump 124, outflow pump 128, or both. In certain embodiments, the pump controller operates inflow pump 124 to fill test socket 114 to a predetermined fill level. Alternatively, pump controller may operate inflow pump 124 until a desired fill level is detected, for example, by one or more sensors, such as a pressure sensor or optical sensor. Similarly, the pump controller may operate outflow pump 128 to remove heated coolant at a selected rate once the desired fill level is detected. The rate may be programmed into memory or, alternatively, user selected. In alternative embodiments, the pump controller may execute a control algorithm for dynamically regulating outflow from test socket 114 based on one or more parameters or setpoints. For example, the pump controller may operate outflow pump 128 to remove heated coolant at rate selected to achieve a desired temperature of the heated coolant.

Test system 100 includes an enclosure 130 within which test site 108 and handler system 104 are disposed. Enclosure 130 supplies a controlled environment for testing IC chips, including, for example, ambient temperature, humidity, or ambient air composition. In at least some embodiments, fluid coolant system 118 may introduce at least some amount of coolant vapor that escapes test site 108. Accordingly, test system 100 includes a ventilation subsystem 132 to vent vapor from inside enclosure 130 or exchange ambient air within enclosure 130 with another volume. Additionally, in certain embodiments, test system 100 may include one or more seals 134, for example, to aid in capturing coolant vapor within enclosure 130 and avoid unwanted leakage through doors, hatches, or other openings in enclosure 130.

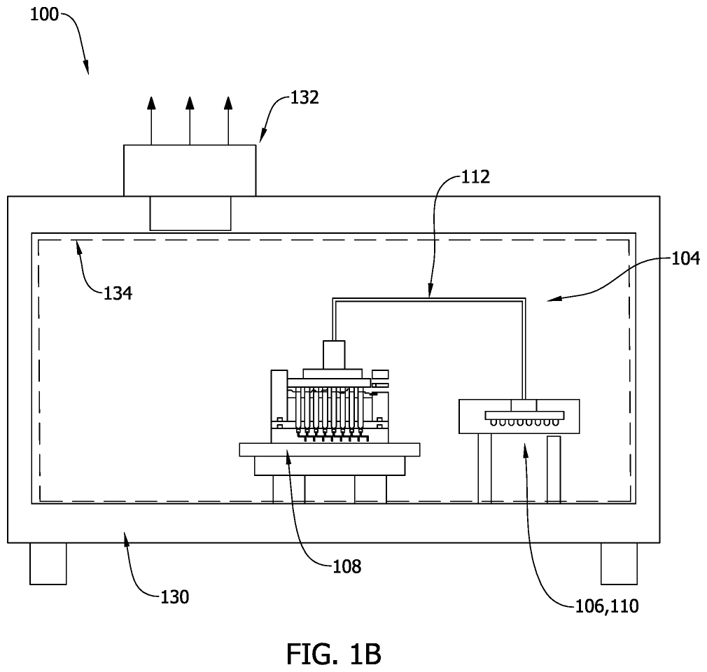

FIG. 2A is a perspective schematic diagram of a test socket 200 for at least partially submerging a plurality of test socket contacts (not shown) in a fluid coolant. FIG. 2B is a perspective cross section view of test socket 200. Test socket 200 includes a housing 202 at least partially defining a chamber 204, one or more inlets 206, and one or more outlets 208. Test socket 200 also includes a guide structure 210 configured to receive an IC chip and position the IC chip in chamber 204 when engaged with the plurality of test socket contacts. Test socket 200 includes a body structure 212 holding a retainer cartridge 214 defining a plurality of cavities (not shown) configured to receive the plurality of test socket contacts. Chamber 204 is configured to receive a fluid coolant via the one or more inlets 206 to at least partially submerge the plurality of test socket contacts in the fluid coolant. In certain embodiments, the fill level of the fluid coolant is sufficient to at least partially submerge the IC chip itself. Inlets 206 and outlets 208 are fluidly coupled to a fluid coolant system, such as fluid coolant system 118 shown in FIG. 1. More specifically, for example, inlets 206 are in fluid communication with inflow pathway 122; and outlets 208 are in fluid communication with outflow pathway 126.

Housing 202 also defines one or more channels to receive seals for retaining the fluid coolant within chamber 204. For example, housing 202 defines channels facing retainer cartridge 214 to receive a cartridge seal 216. Cartridge seal 216 prevents fluid coolant leakage at the interface between housing 202 and retainer cartridge 214.

Retainer cartridge 214 defines additional channels configured to face a load board. The additional channels receive a PCB seal 218. As fluid coolant flows around test socket contacts through cavities defined in retainer cartridge 214, PCB seal 218 prevents fluid coolant leakage at the interface between test socket 200 and a load board.

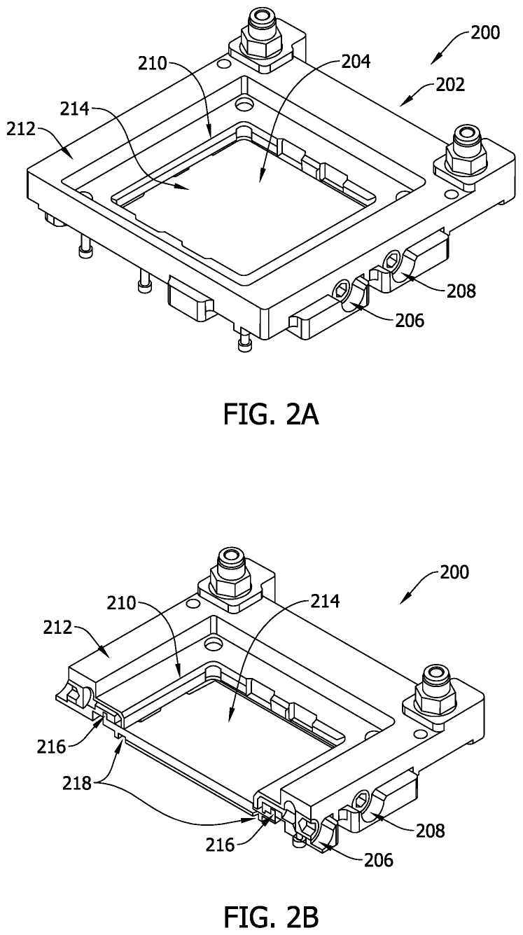

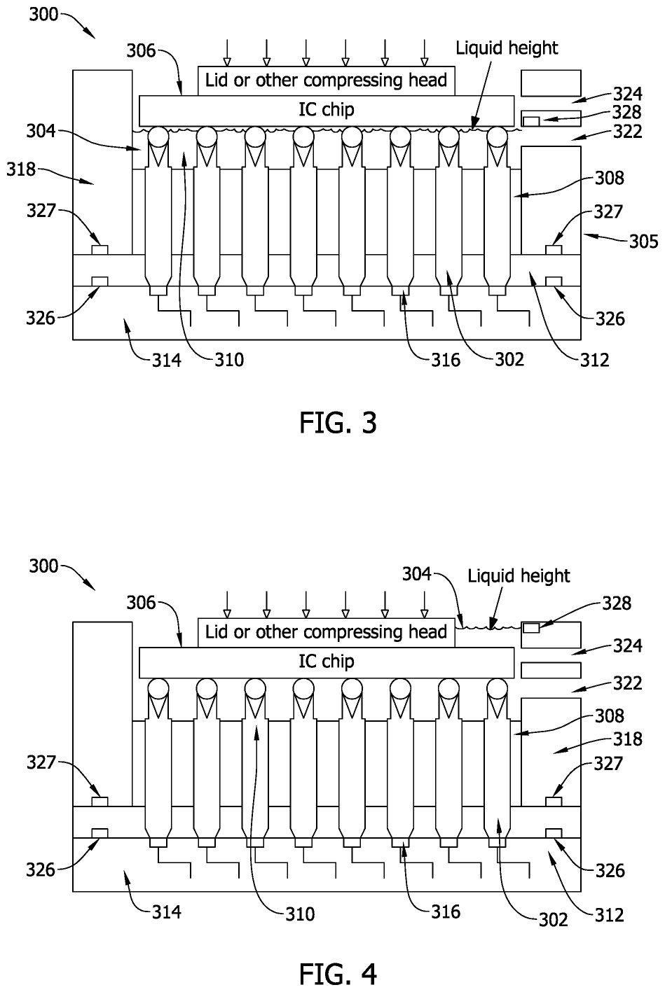

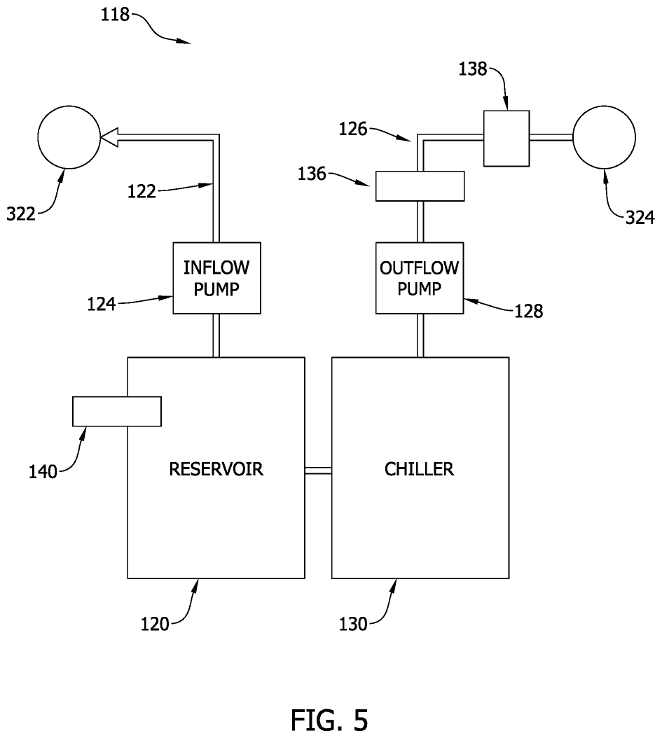

FIG. 3 is a cross sectional diagram of a test socket 300 for at least partially submerging test socket contacts 302 in a fluid coolant 304. FIG. 4 is a cross sectional diagram of another embodiment of the test socket 300 shown in FIG. 3, for at least partially submerging the IC chip 306 in the fluid coolant 304. FIG. 5 is a schematic diagram of an example fluid coolant system for use with a test socket such as test socket 300 shown in FIG. 3 or FIG. 4. Referring to FIGS. 3 and 4, test socket 300 includes a housing 305 at least partially defining a chamber 310. Test socket includes a body structure 308 defining a plurality of cavities in which test socket contacts 302 are disposed to electrically connect IC chip 306 and a load board 314. The cavities are sized to receive test socket contacts 302, and permit fluid flow within chamber 310 and, more specifically, between the interface between IC chip 306 and test socket contacts 302 and the interface between test socket contacts 302 and load board 314. Test socket 300 includes a retainer 312 positioned adjacent to load board 314, for example, mounted to a top surface of load board 314. Load board 314 includes a plurality of contact pads 316. Retainer 312 defines a plurality of apertures corresponding to the contact pads 316 on load board 314 and corresponding to the cavities in body structure 308. Test socket contacts 302 are disposed in the apertures of retainer 312 and cavities of body structure 308, and electrically couple IC chip 306 to contact pads 316 on load board 314 for the purpose of conducting electrical tests on IC chip 306.

Test socket 300 includes a guide structure 318 configured to receive IC chip 306 and position IC chip 306 in chamber 310 when engaged with test socket contacts 302. Guide structure 318 enables precise insertion of IC chip 306 into chamber 310, for example, by an auto handler system such as that shown in FIG. 1. Housing 305 further defines one or more inlets 322 and one or more outlets 324. Inlets 322 and outlets 324 are in fluid communication with a fluid coolant system, such as fluid coolant system 118 shown in FIG. 1. Inlets 322 enable introduction of fluid coolant 304, such as a liquid coolant, into chamber 310. Fluid coolant fills around test socket contacts 302, through retainer 312 to a top surface of load board 314. One or more PCB seals 326 are positioned between retainer 312 and load board 314 to prevent fluid coolant from escaping between test socket 300 and load board 314. Additional cartridge seals 327 are also positioned between retainer 312 and guide structure 318 or, alternatively, between retainer 312 and body structure 308, of test socket 300. In alternative embodiments, body structure 308, guide structure 318, and retainer 312 may be incorporated into a single unitary structure, thereby eliminating the need for seals, for example, between retainer 312 and guide structure 318. Body structure 308, guide structure 318, and retainer 312 may be fabricated from a metal, metal alloy, or a plastic. For example, body structure 308, guide structure 318, and retainer 312 may be fabricated from aluminum, magnesium, titanium, zirconium, copper, iron, or any alloy thereof, such as aluminum 5053. Alternatively, body structure 308, guide structure 318, and retainer 312 may be fabricated, for example from PEEK, ceramic PEEK, MDS100, SCP 5000, or other suitable material.

Fluid coolant fills chamber 310 until a desired fill level is reached. For example, body structure 308 includes a sensor 328 configured to detect the fill level within the chamber 310. In the embodiment of FIG. 3, sensor 328 is positioned at a level equal to that of IC chip 306. Accordingly, fluid coolant 304 submerges test socket contacts 302. Similarly, in the embodiment of FIG. 4, sensor 328 is positioned at a level above a top surface of IC chip 306. Accordingly, fluid coolant 304 submerges test socket contacts 302 and at least a portion of IC chip 306. In certain embodiments, one or more additional sensors may be positioned in the chamber, for example, to measure coolant temperature within the chamber.

FIG. 5 illustrates fluid coolant system 118 shown in FIG. 1 for use with test socket 300. Fluid coolant system 118 includes reservoir 120 fluidly coupled to inflow pump 124. In certain embodiments, one or more sensors 140 may be included within reservoir 120 to measure the fill level of fluid coolant within reservoir 120. Inflow pump 124 moves fluid coolant from reservoir 120 through inflow pathway 122 to inlet 322 of test socket 300. Heated coolant exits test socket 300 through outlet 324 and flows back to fluid coolant system 118 via outflow pathway 126. Outflow pathway 126 fluidly couples to outflow pump 128 to aid in moving heated coolant back toward reservoir 120 for recirculation. Outflow pathway 126 may include a pressure sensor 136 for measuring fluid pressure of heated coolant flowing from outlet 324. Outflow pathway 126 may include a filtration system 138 for capturing particulates or other contaminates from the heated coolant before it is returned to reservoir 120.

Fluid coolant system 118 includes a chiller 130 that receives the heated coolant from outflow pathway 126 and chills the fluid coolant to a temperature suitable for recirculation to test socket 300 again. In certain embodiments, where the fluid coolant exits test socket 300 as a vapor, chiller 130 also condenses the fluid coolant back to a liquid state. Once the fluid coolant is cooled and condensed, it flows back to reservoir 120 for recirculation.

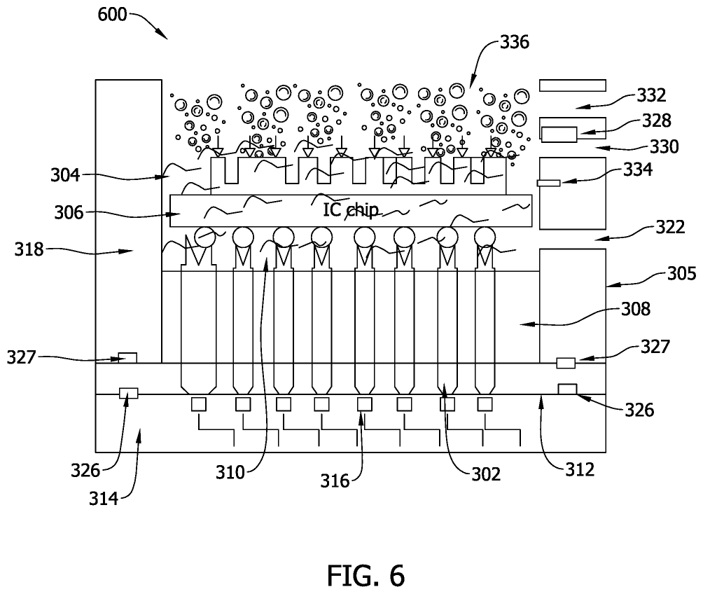

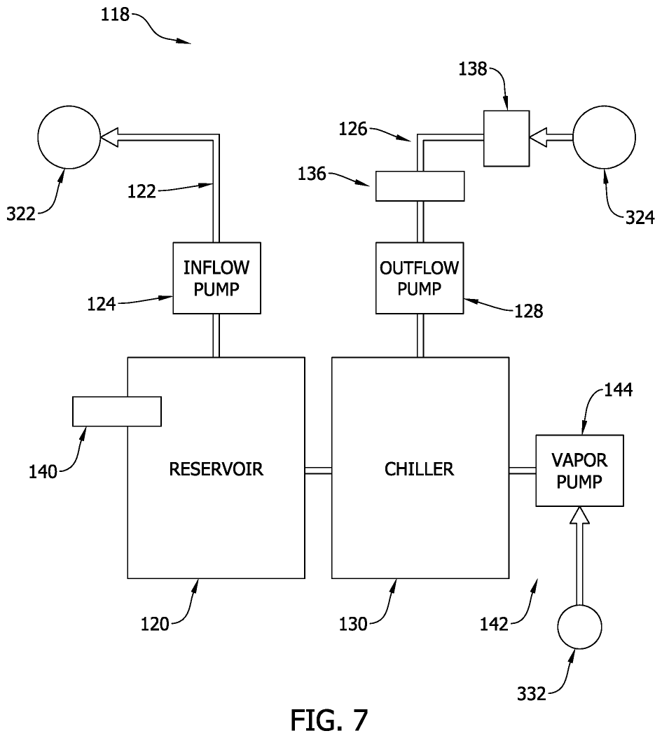

FIG. 6 is a cross sectional diagram of a test socket 600 for at least partially submerging test socket contacts 302 in fluid coolant 304. More specifically, test socket 600 is configured for a two phase coolant, i.e., one that operates in both a liquid phase and a gas phase in the cooling process. To the extent similar components of test socket 300 shown in FIGS. 3 and 4 are included in test socket 600, common part numbers are used in the description of test socket 600. FIG. 7 is a schematic diagram of an example fluid coolant system 118 for use with a test socket such as test socket 600 shown in FIG. 6. Referring to FIG. 6, test socket 600 includes housing 305 at least partially defining chamber 310. Test socket 600 includes body structure 308 defining a plurality of cavities in which test socket contacts 302 are disposed to electrically connect IC chip 306 and a load board 314. The cavities are sized to receive test socket contacts 302, and permit fluid flow within chamber 310 and, more specifically, between the interface between IC chip 306 and test socket contacts 302 and the interface between test socket contacts 302 and load board 314. Test socket 600 includes retainer 312 positioned adjacent to load board 314, for example, mounted to a top surface of load board 314. Load board 314 includes plurality of contact pads 316. Retainer 312 defines a plurality of apertures corresponding to the contact pads 316 on load board 314 and corresponding to the cavities in body structure 308. Test socket contacts 302 are disposed in the apertures of retainer 312 and cavities of body structure 308, and electrically couple IC chip 306 to contact pads 316 on load board 314 for the purpose of conducting electrical tests on IC chip 306.

Test socket 600 includes guide structure 318 configured to receive IC chip 306 and position IC chip 306 in chamber 310 when engaged with test socket contacts 302. Guide structure 318 enables precise insertion of IC chip 306 into chamber 310, for example, by an auto handler system such as that shown in FIG. 1. Housing 305 further defines one or more inlets 322, one or more liquid outlets 324, and one or more vapor outlets 330. Inlets 322, liquid outlets 3330, and vapor outlets 332 are in fluid communication with a two phase fluid coolant system, such as fluid coolant system 118 shown in FIG. 1 or FIG. 7. Inlets 322 enable introduction of fluid coolant 304, such as a liquid coolant, into chamber 310. Fluid coolant fills around test socket contacts 302, through retainer 312 to a top surface of load board 314. One or more PCB seals 326 are positioned between retainer 312 and load board 314 to prevent fluid coolant from escaping between test socket 600 and load board 314. Additional cartridge seals 327 are also positioned between retainer 312 and guide structure 318 or, alternatively, between retainer 312 and body structure 308, of test socket 600. In alternative embodiments, body structure 308, guide structure 318, and retainer 312 may be incorporated into a single unitary structure, thereby eliminating the need for seals, for example, between retainer 312 and guide structure 318. Body structure 308, guide structure 318, and retainer 312 may be fabricated from a metal, metal alloy, or a plastic. For example, body structure 308, guide structure 318, and retainer 312 may be fabricated from aluminum, magnesium, titanium, zirconium, copper, iron, or any alloy thereof, such as aluminum 5053. Alternatively, body structure 308, guide structure 318, and retainer 312 may be fabricated, for example from PEEK, ceramic PEEK, MDS100, SCP 5000, or other suitable material.

Fluid coolant fills chamber 310 until a desired fill level is reached. For example, body structure 308 includes sensor 328 configured to detect the fill level within the chamber 310. In the embodiment of FIG. 6, sensor 328 is positioned at a level above a top surface of IC chip 306. Accordingly, fluid coolant 304 submerges test socket contacts 302 and at least a portion of IC chip 306. In certain embodiments, one or more additional sensors 334 may be positioned in the chamber, for example, to measure coolant temperature within the chamber.

FIG. 7 illustrates fluid coolant system 118 shown in FIG. 1 for use with a two phase coolant and test socket 600. Fluid coolant system 118 includes reservoir 120 fluidly coupled to inflow pump 124. In certain embodiments, one or more sensors 140 may be included within reservoir 120 to measure the fill level of fluid coolant within reservoir 120. Inflow pump 124 moves fluid coolant from reservoir 120 through inflow pathway 122 to inlet 322 of test socket 600. Heated liquid coolant exits test socket 600 through liquid outlet 330 and flows back to fluid coolant system 118 via outflow pathway 126. Outflow pathway 126 fluidly couples to outflow pump 128 to aid in moving heated coolant back toward reservoir 120 for recirculation. Outflow pathway 126 may include a pressure sensor 136 for measuring fluid pressure of heated coolant flowing from liquid outlet 330. Outflow pathway 126 may include a filtration system 138 for capturing particulates or other contaminates from the heated coolant before it is returned to reservoir 120. Likewise, some heated coolant vaporizes and the coolant vapor 336 exits test socket 600 through vapor outlet 332 and flows back to fluid coolant system 118 via vapor pathway 142. Vapor pathway 142 fluidly couples to a vapor pump 144 to aid in moving coolant vapor back toward chiller 130 for condensing and eventually to reservoir 120 for recirculation.

Fluid coolant system 118 includes a chiller 130 that receives the heated coolant from outflow pathway 126 and chills the fluid coolant to a temperature suitable for recirculation to test socket 300 again. In certain embodiments, where the fluid coolant exits test socket 300 as a vapor, chiller 130 also condenses the fluid coolant back to a liquid state. Once the fluid coolant is cooled and condensed, it flows back to reservoir 120 for recirculation.

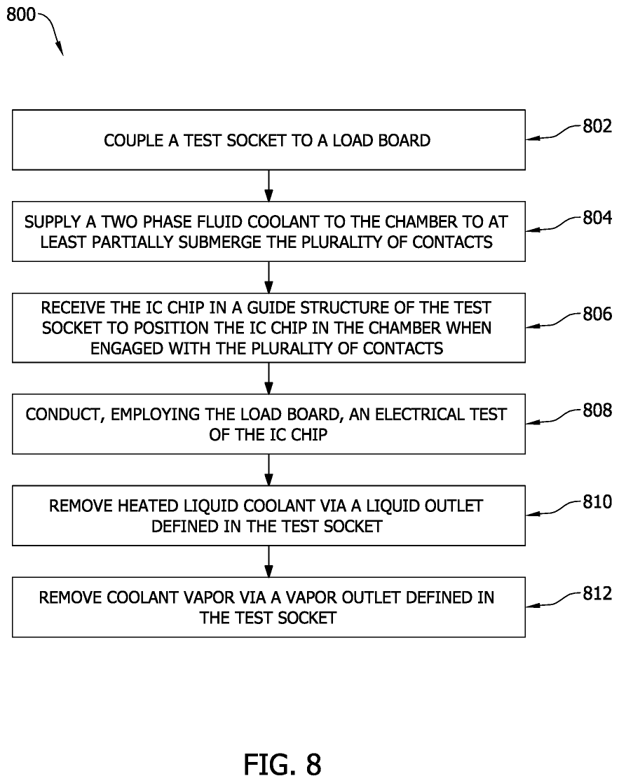

FIG. 8 is a flow diagram of one embodiment of a method 800 of testing an IC chip, such as IC chip 306 shown in FIG. 6, using a test socket, such as test socket 600 shown in FIG. 6. Test socket 600 is coupled 802 to load board 314. Test socket 600 defines chamber 310 within which test socket contacts 302 are disposed. Test socket contacts 302 are configured to electrically couple IC chip 306 to load board 314. A two phase fluid coolant is supplied 804 to chamber 310 to at least partially submerge the plurality of test socket contacts 302. In certain embodiments, the two phase fluid coolant is supplied to chamber 310 to at least partially submerge IC chip 306 in addition to test socket contacts 302. Guide structure 318 receives 806 IC chip 306 and guides it precisely into chamber 310 and, more specifically, into engagement with test socket contacts 302.

Once IC chip 306 is in position within test socket 600, load board 314 is employed to conduct 808 an electrical test of IC chip 306. The electrical tests generally result in significant amounts of power consumed by IC chip 306, and current conducted through at least some test socket contacts 302, resulting in substantial heating of test socket 600 and, more specifically, test socket contacts 302, housing 305, and IC chip 306. The two phase fluid coolant in which at least test socket contacts 302 are at least partially submerged is circulated within chamber 310 and, once heated sufficiently, removed from chamber 310. Heated liquid coolant is removed 810 via a liquid outlet 330 defined in test socket 600. When heated liquid coolant is heated to a vaporization threshold, the coolant vapor is removed 612 through vapor outlet 332.

Liquid and vapor coolant are returned to a chiller for cooling and condensing, and then flow to reservoir 120 for recirculation to test socket 600. When the electrical test is complete, IC chip 306 is removed from test socket 600 and is passed into an output container. Test socket 600 can then be employed to conduct electrical tests on a next IC chip 306.

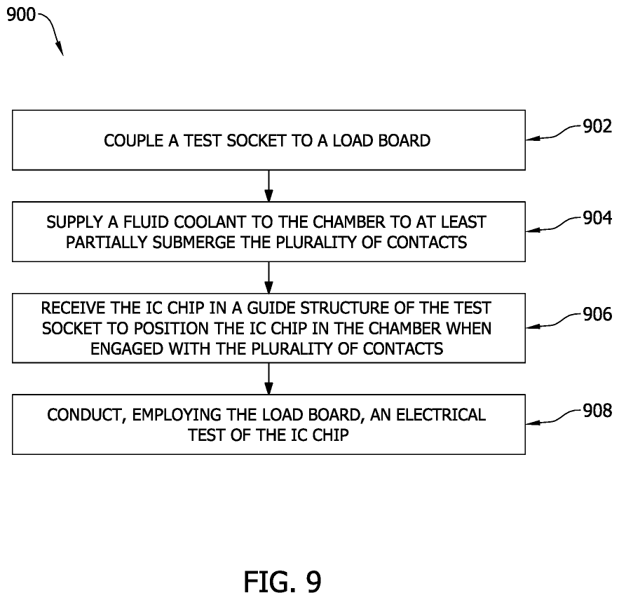

FIG. 9 is a flow diagram of one embodiment of a method 900 of testing an IC chip, such as IC chip 306 shown in FIGS. 3 and 4, using a test socket, such as test socket 300 shown in FIGS. 3 and 4. Test socket 300 is coupled 902 to load board 314. Test socket 300 defines chamber 310 within which test socket contacts 302 are disposed. Test socket contacts 302 are configured to electrically couple IC chip 306 to load board 314. A fluid coolant is supplied 904 to chamber 310 to at least partially submerge the plurality of test socket contacts 302. In certain embodiments, the fluid coolant is supplied to chamber 310 to at least partially submerge IC chip 306 in addition to test socket contacts 302. Guide structure 318 receives 906 IC chip 306 and guides it precisely into chamber 310 and, more specifically, into engagement with test socket contacts 302.

Once IC chip 306 is in position within test socket 300, load board 314 is employed to conduct 908 an electrical test of IC chip 306. The electrical tests generally result in significant amounts of power consumed by IC chip 306, and current conducted through at least some test socket contacts 302, resulting in substantial heating of test socket 300 and, more specifically, test socket contacts 302, housing 305, and IC chip 306. The fluid coolant in which at least test socket contacts 302 are at least partially submerged is circulated within chamber 310 and, once heated sufficiently, removed from chamber 310. For example, when a liquid coolant is heated to a vaporization threshold, the coolant vapor is removed through outlets 324 and an outflow pathway to return the coolant to a reservoir for cooling and recirculation to test socket 300. When the electrical test is complete, IC chip 306 is removed from test socket 300 and is passed into an output container. Test socket 300 can then be employed to conduct electrical tests on a next IC chip 306.

Example technical effects of the methods, systems, and apparatus described herein include at least one of: (a) submerging at least test socket contacts at least partially in a fluid coolant to directly cool the test socket contacts, the interface between the test socket contacts and the load board, and the interface between the test socket contacts and the IC chip; (b) submerging an IC chip under test at least partially in a fluid coolant to directly cool the IC chip and test socket housing in addition to the test socket contacts; (c) maintaining signal integrity through test socket contacts submerged in a non-conductive and low dielectric constant fluid coolant; (d) improving heat absorbing capacity and heat releasing capacity of a fluid coolant by use of a fluid coolant that is in a liquid state at about room temperature and having a low vaporization threshold; (e) improving heat absorbing capacity and heat releasing capacity of a single phase coolant by increasing flow rate through the test socket; (f) control flow of fluid coolant supply and removal to and from the test socket to achieve a desired coolant temperature, test socket contact temperature, IC chip temperature, or other suitable parameter; (g) improving test socket contact useful life; and (h) reducing down time of test system for replacing test socket contacts.

At least some example embodiments of the disclosed test sockets and methods include:
(1) A test socket for an integrated circuit (IC) chip, the test socket comprising: a retainer configured to be positioned adjacent a load board, the retainer defining a plurality of apertures corresponding to contact pads on the load board; a plurality of contacts disposed in the plurality of apertures, the plurality of contacts configured to electrically couple the IC chip to the contact pads; and a housing at least partially defining a chamber in fluid communication with an inlet, a liquid outlet and a vapor outlet, the housing comprising: a guide structure configured to receive the IC chip and position the IC chip in the chamber when engaged with the plurality of contacts; wherein the chamber is configured to receive a two phase fluid coolant via the inlet to at least partially submerge the plurality of contacts in the two phase fluid coolant.
(2) The test socket of example 1, wherein the plurality of contacts comprises a plurality of coaxial contact probes.
(3) The test socket of example 1, wherein the plurality of contacts comprises a plurality of rotational contacts.
(4) The test socket of example 1, wherein the chamber is further configured to receive a perfluorinated compound as the two phase fluid coolant.
(5) The test socket of example 1 further comprising a sensor disposed on the housing and configured to detect a temperature of the two phase fluid coolant within the chamber.
(6) The test socket of example 1, further comprising a sensor disposed on the housing and configured to detect a fill level of the two phase fluid coolant within the chamber, wherein the sensor is positioned to detect the fill level such that the plurality of contacts is at least partially submerged in the two phase fluid coolant.
(7) The test socket of example 1, further comprising a sensor disposed on the housing and configured to detect a fill level of the two phase fluid coolant within the chamber, wherein the sensor is positioned to detect the fill level such that the IC chip is at least partially submerged in the two phase fluid coolant.
(8) The test socket of example 1, wherein the chamber is further configured to receive the two phase fluid coolant in liquid state at room temperature, and wherein the fluid coolant has a vaporization threshold of no more than 60 degrees Celsius.
(9) A test socket for an integrated circuit (IC) chip, the test socket comprising: a retainer configured to be positioned adjacent a load board, the retainer defining a plurality of apertures corresponding to contact pads on the load board; a plurality of contacts disposed in the plurality of apertures, the plurality of contacts configured to electrically couple the IC chip to the contact pads; and a housing at least partially defining a chamber in fluid communication with an inlet, and an outlet, the housing comprising: a guide structure configured to receive the IC chip and position the IC chip in the chamber when engaged with the plurality of contacts; wherein the chamber is configured to receive a fluid coolant via the inlet to at least partially submerge the plurality of contacts in the fluid coolant.
(10) The test socket of example 9, wherein the plurality of contacts comprises a plurality of coaxial contact probes.
(11) The test socket of example 10, wherein the plurality of contacts comprises a plurality of rotational contacts.
(12) The test socket of example 10, wherein the chamber is further configured to receive a perfluorinated compound as the fluid coolant.
(13) The test socket of example 10 further comprising a sensor disposed on the housing and configured to detect a fill level of the fluid coolant within the chamber.
(14) The test socket of example 13, wherein the sensor is positioned to detect the fill level such that the plurality of contacts is at least partially submerged in the fluid coolant.
(15) The test socket of example 14, wherein the sensor is positioned to detect the fill level such that the IC chip is at least partially submerged in the fluid coolant.
(16) The test socket of example 10, wherein the chamber is further configured to receive the fluid coolant in liquid state at room temperature, and wherein the fluid coolant has a vaporization threshold of no more than 60 degrees Celsius.
(17) A method of testing an integrated circuit (IC) chip, said method comprising: coupling a test socket to a load board, the test socket defining a chamber within which a plurality of contacts is disposed, the plurality of contacts configured to electrically couple the IC chip to the load board; supplying a fluid coolant to the chamber to at least partially submerge the plurality of contacts; receiving the IC chip in a guide structure of the test socket to position the IC chip in the chamber when engaged with the plurality of contacts; and conducting, employing the load board, an electrical test of the IC chip.
(18) The method of example 17 further comprising removing the IC chip from the test socket upon completion of the electrical test.
(19) The method of example 17 further comprising removing heated fluid coolant from the chamber.
(20) The method of example 17 further comprising supplying the fluid coolant to the chamber to at least partially submerge the IC chip.

The systems and methods described herein are not limited to the specific embodiments described herein, but rather, components of the systems and/or steps of the methods may be utilized independently and separately from other components and/or steps described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

As used herein, an element or step recited in the singular and proceeded with the word “a” or “an” should be understood as not excluding plural elements or steps unless such exclusion is explicitly recited. Furthermore, references to “one embodiment” of the present disclosure or “an example embodiment” are not intended to be interpreted as excluding the existence of additional embodiments that also incorporate the recited features.

Disjunctive language such as the phrase “at least one of X, Y, or Z,” unless specifically stated otherwise, is generally understood within the context as used to state that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

This written description uses examples to disclose various embodiments, which include the best mode, to enable any person skilled in the art to practice those embodiments, including making and using any devices or systems and performing any incorporated methods. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A test system for a plurality of integrated circuit (IC) chips, comprising:
a test site comprising:
a test socket coupled to a load board, the test socket comprising:
a housing at least partially defining a chamber;
a plurality of contacts disposed within a retainer structure within the chamber and electrically coupled to the load board; and
a guide structure configured to receive each of the plurality of IC chips and position each IC chip in the chamber when engaged with the plurality of contacts;
a fluid coolant system comprising:
a reservoir configured to hold a fluid coolant;
an inlet pathway coupled between the reservoir and the test socket, the inlet pathway configured to carry the fluid coolant to the test socket to at least partially fill the chamber and to at least partially submerge the plurality of contacts; and
an outlet pathway coupled between the reservoir and the test socket, the outlet pathway configured to carry heated coolant away from the test socket; and
a handler system configured to move the plurality of IC chips from a feed container to the test site, and from the test site to an output container, the handler system comprising a pick arm configured to set each IC chip into the guide structure of the test socket to engage with the plurality of contacts at least partially submerged in the fluid coolant.

2. The test system of claim 1, wherein the test site further comprises a load board configured to conduct an electrical test on the IC chip.

3. The test system of claim 1, wherein the test site comprises a plurality of test sockets coupled to the fluid coolant system.

4. The test system of claim 1, wherein the fluid coolant system comprises an inflow pump coupled to the reservoir and the inlet pathway, the inflow pump configured to move the fluid coolant through the inlet pathway into the chamber of the test socket until a fill level is reached.

5. The test system of claim 1, wherein the fluid coolant system comprises an outflow pump coupled to the reservoir and the outlet pathway, the outflow pump configured to move the fluid coolant from the chamber of the test socket through the outlet pathway at a selected flow rate.

6. The test system of claim 5, wherein the fluid coolant system further comprises a pump controller configured to operate the outflow pump according to a user selected flow rate setting.

7. The test system of claim 1, wherein the test socket further comprises a sensor disposed on the housing and configured to detect a fill level of the fluid coolant within the chamber such that the plurality of contacts is at least partially submerged in the fluid coolant.

8. The test system of claim 7, wherein the sensor is positioned to detect the fill level such that each IC chip is at least partially submerged in the fluid coolant.

9. A test system for a plurality of integrated circuit (IC) chips, comprising:
a test site comprising:
a test socket coupled to a load board, the test socket comprising:
a housing at least partially defining a chamber;
a plurality of contacts disposed within a retainer structure within the chamber and electrically coupled to the load board; and
a guide structure configured to receive each of the plurality of IC chips and position each IC chip in the chamber when engaged with the plurality of contacts;
a fluid coolant system comprising:
a reservoir configured to hold a two phase fluid coolant;
an inlet pathway coupled between the reservoir and the test socket, the inlet pathway configured to carry the two phase fluid coolant to the test socket to at least partially fill the chamber and to at least partially submerge the plurality of contacts; and
a liquid outlet pathway coupled between the reservoir and the test socket, the liquid outlet pathway configured to carry heated liquid coolant away from the test socket;
a vapor outlet pathway coupled between the reservoir and the test socket, the vapor outlet pathway configured to carry coolant vapor away from the test socket; and
a handler system configured to move the plurality of IC chips from a feed container to the test site, and from the test site to an output container, the handler system comprising a pick arm configured to set each IC chip into the guide structure of the test socket to engage with the plurality of contacts at least partially submerged in the two phase fluid coolant.

10. The test system of claim 9, wherein the test site further comprises the load board, wherein the load board is configured to conduct an electrical test on the IC chip.

11. The test system of claim 9, wherein the test site comprises a plurality of test sockets coupled to the fluid coolant system.

12. The test system of claim 9, wherein the fluid coolant system comprises an inflow pump coupled to the reservoir and the inlet pathway, the inflow pump configured to move the two phase fluid coolant through the inlet pathway into the chamber of the test socket until a fill level is reached.

13. The test system of claim 9, wherein the fluid coolant system comprises an outflow pump coupled to the reservoir and the liquid outlet pathway, the outflow pump configured to move heated liquid coolant from the chamber of the test socket through the liquid outlet pathway at a selected flow rate.

14. The test system of claim 13, wherein the fluid coolant system further comprises a vapor pump coupled to the reservoir and the vapor outlet pathway, the vapor pump configured to move heated coolant vapor from the chamber of the test socket through the vapor outlet pathway at a selected flow rate.

15. The test system of claim 9, wherein the fluid coolant system further comprises a filtration system fluidly coupled in the liquid outlet pathway to remove contaminants from heated liquid coolant.

16. The test system of claim 9, wherein the fluid coolant system further comprises a sensor coupled in the liquid outlet pathway and configured to measure a pressure of heated liquid coolant flowing from the test socket.

17. The test system of claim 9 further comprising an enclosure within which the test site and the handler system are disposed, wherein the enclosure includes a ventilation system configured to vent coolant vapor emitted from the test site.

18. A method of testing an integrated circuit (IC) chip, said method comprising:
coupling a test socket to a load board, the test socket defining a chamber within which a plurality of contacts is disposed, the plurality of contacts configured to electrically couple the IC chip to the load board;
supplying a two phase fluid coolant to the chamber to at least partially submerge the plurality of contacts;
receiving the IC chip in a guide structure of the test socket to position the IC chip in the chamber when engaged with the plurality of contacts;
conducting, employing the load board, an electrical test of the IC chip; and
removing heated fluid coolant from the chamber, including:
removing heated liquid coolant via a liquid outlet defined in the test socket; and
removing coolant vapor via a vapor outlet defined in the test socket.

19. The method of claim 18 further comprising removing the IC chip from the test socket upon completion of the electrical test.

20. The method of claim 18 further comprising supplying the fluid coolant to the chamber to at least partially submerge the IC chip.
